(19) United States
(12) Patent Application Publication
(10) Pub. No.: US 2015/0303040 A1
(43) Pub. Date: Oct. 22, 2015

(54) Tungsten Sintered Compact Sputtering Target and Tungsten Film Formed Using Said Target

(71) Applicant: JX Nippon Mining & Metals Corporation, Tokyo (JP)

(72) Inventors: Kengo Kaminaga, Ibaraki (JP); Kazumasa Ohashi, Ibaraki (JP)

(73) Assignee: JX Nippon Mining & Metals Corporation, Tokyo (JP)

(21) Appl. No.: 14/418,039

(22) PCT Filed: Oct. 24, 2013
(86) PCT No.: PCT/JP2013/078833

§ 371 Date: Jan. 28, 2015

(30) Foreign Application Priority Data
Nov. 2, 2012 (JP) 2012-242796

(51) Int. Cl. H01J 37/34; C22C 27/04; C23C 14/16

(52) U.S. Cl. CPC H01J 37/3426; C23C 14/165; C22C 27/04; H01J 2237/3322

(57) ABSTRACT

A tungsten sintered compact sputtering target, wherein a molybdenum strength detected with a secondary ion mass spectrometer (D-SIMS) is equal to or less than 1/10000 of the tungsten strength. This invention aims to reduce the specific resistance of a tungsten film sputtered using the tungsten sintered compact target by reducing the molybdenum in the tungsten sintered compact sputtering target and adjusting the grain size distribution of the W powder that is used during sintering.

### BACKGROUND

The present invention relates to a tungsten sintered compact target that is used upon forming, via the sputtering method, a gate electrode or a wiring material of an IC, LSI or the like, and to a tungsten film formed using the foregoing target.

In recent years, pursuant to the higher integration of very-large-scale integrated circuits (“VLSI”), studies are being conducted for using materials having lower electrical resistivity as the electrode material or the wiring material. Under the foregoing circumstances, high-purity tungsten having low resistivity and stable thermal and chemical characteristics is being used as the electrode material or the wiring material.

The foregoing electrode material or wiring material for VLSI is generally produced by way of the sputtering method or the CVD method, but the sputtering method is being widely used in comparison to the CVD method since the structure and operation of the device are relatively simple, deposition can be performed easily, and the process is of low cost.

While a tungsten target is demanded of high purity and high density, in recent years, as an electrode material or a wiring material for VLSI, a material with even lower electrical resistivity is being demanded in a film deposited by sputtering a tungsten target.

As described later, a tungsten sintered compact target is capable of attaining higher purity and high densification, and, while there are disclosures for achieving such higher purity and high densification, the conditions required for lowering the electrical resistivity are unclear, and research and development for lowering the electrical resistivity have not been conducted sufficiently.

Consequently, there is a problem in that a tungsten thin film formed via sputtering has a high specific resistance that is double that of its theoretical specific resistance, and its inherent high conductivity is not being sufficiently yielded.

Upon reviewing the Prior Art Documents relating to the tungsten sintered compact sputtering target, Patent Document 1 describes a method of producing a tungsten sputtering target characterized in pulverizing a high purity tungsten powder having a purity of 99.999% or higher in a molybdenum ball mill so as to attain a molybdenum content of 5 to 100 ppm and an average grain size of 1 to 5 μm, and subjecting the obtained tungsten powder compact to pressure sintering in a vacuum or an inert gas atmosphere, and a sputtering target obtained thereby. In the foregoing case, since a molybdenum ball mill is used, molybdenum inevitably gets mixed in, and the influence of molybdenum as an impurity cannot be ignored.

Patent Document 2 describes a tungsten sputtering target characterized in that the relative density of the target is 99% or higher, the Vickers hardness is 330 Hv or more, and the variation in the Vickers hardness of the overall target is 30% or less, and a tungsten sputtering target characterized in that the total content of Fe, Ni, Cr, Cu, Al, Na, K, U and Th as the impurities contained in the foregoing target is less than 0.01 mass %. In the foregoing case, Patent Document 2 is taking interest in the hardness of the target, and makes no reference to the problem of the specific resistance of the target or the influence from the inclusion of molybdenum.

Patent Document 3 describes a method of producing a target for sputtering characterized in heating, pressing and holding a mixture of a high melting point substance powder having a melting point of 900° C. or higher and a low melting point metal powder having a melting point of 700° C. or less at a temperature that is less than the melting point of the low melting point metal, and Patent Document 3 describes W as an example of the high melting point substance powder. Nevertheless, in the foregoing case also, Patent Document 3 makes no reference to the problem of the specific resistance of the target or the influence from the inclusion of molybdenum.

Patent Document 4 aims to obtain a tungsten-based sintered compact having a relative density of 99.5% or higher (volume ratio of pores is 0.5% or less) and a structure that is uniform and isotropic, and describes obtaining a tungsten-based sintered compact by performing CIP treatment to a tungsten-based powder at a pressure of 350 MPa or higher, performing sintering under the following conditions; namely, in a hydrogen gas atmosphere, at a sintering temperature of 1600° C. or higher, and a holding time of 5 hours or longer, and performing HIP treatment under the following conditions; namely, in an argon gas atmosphere, a pressure of 150 MPa or higher, and a temperature of 1900° C. or higher. Moreover, Patent Document 4 also describes the following usages of its tungsten-based sintered compact; specifically, an electrode for an electric-discharge lamp, a sputtering target, a crucible, a radiation shielding member, an electrode for electrical discharge machining, a semiconductor element-mounting substrate, and a structural member. Nevertheless, in the foregoing case also, Patent Document 4 makes no reference to the problem of the specific resistance of the target or the influence from the inclusion of molybdenum.

Patent Document 5 describes a method of producing a tungsten sintered compact target for sputtering characterized in that a tungsten powder having a powder specific surface area of 0.4 m²/g (BET method) or more is used, hot press sintering is performed in a vacuum or a reduction atmosphere at a pressure starting temperature of 1200° C. or less, and hot isostatic pressure sintering (HIP) is thereafter performed. Patent Document 5 describes that, by improving the sintering characteristics and the production conditions of the tungsten powder to be used, it is possible to obtain a tungsten target for sputtering having a high density and fine crystal structure, which could not be achieved with conventional pressure sintering methods, dramatically improve the deflective strength, suppress the generation of particle defects that occur during the deposition via sputtering, and achieve a method capable of stably producing the foregoing tungsten target at a low cost. While this technique is effective for obtaining a tungsten target with an improved deflective strength, in the foregoing case also, Patent Document 5 makes no reference to the problem of the specific resistance of the target or the influence from the inclusion of molybdenum.

Patent Document 6 describes a method of producing a tungsten target for sputtering having a oxygen content of 0.1 to 10 ppm, a relative density of 99% or higher, and a crystal grain size of 80 μm or less characterized in performing plasma treatment of generating a plasma between the tungsten powder surfaces by applying a high-frequency current to the tungsten powder in a vacuum, and thereafter performing pressure sintering in a vacuum, and a tungsten sputtering target obtained from the foregoing method. While this technique is effective for achieving high densification and a lower oxygen content, in the foregoing case also, Patent Document 6 makes no reference to the problem of the specific resistance of the target or the influence from the inclusion of molybdenum.

Patent Document 7 describes that, when a tungsten sintered compact sputtering target is produced using a conventional carbon die, a large amount of carbon is contained as an impurity within the sintered compact target and, as the carbon content increases, the specific resistance of the tungsten film after sputtering deposition tends to increase. In order to resolve the foregoing problem, Patent Document 7 proposes adopting the method of reducing, as much as possible, the area that comes into contact with C and, by causing the carbon content to be 5 ppm or less, causing the specific resistance of the tungsten film after deposition to be 12.3 μΩ·cm or less. Nevertheless, these conditions for reducing the specific resistance value are insufficient, and it cannot be said that Patent Document 7 yields a sufficient effect.

Patent Document 8 discloses a component including a metal composition made from one or more materials selected from a group consisting of metal molybdenum, metal hafnium, metal zirconium, metal rhenium, metal ruthenium, metal platinum, metal tantalum, metal tungsten and metal iridium, wherein the metal composition contains a plurality of grains, the numerous grains are substantially isometric, the grains have an average grain size of approximately 30 microns or less when the composition contains metal molybdenum, an average grain size of approximately 150 microns or less when the composition contains metal ruthenium, an average grain size of approximately 15 microns or less when the composition contains metal tungsten, and an average grain size of approximately 50 microns or less when the composition contains metal hafnium, metal rhenium, metal tantalum, metal zirconium, metal platinum, or metal iridium. In addition, Patent Document 8 describes that the representative component is a sputtering target.

This technique aims to improve the uniformity of the thin film formed via sputtering, and therefore adopts a means for refining the grains of the composition. Nevertheless, Patent Document 8 offers no disclosure regarding what types of factors affect the reduction of electrical resistivity of a thin film, or the solution thereof, particularly in the case of a tungsten target.

### PRIOR ART DOCUMENTS

### Patent Documents

Japanese Patent Application Publication No. 2001-295036
Japanese Patent Application Publication No. 2003-171760
WO1996/036746
WO2005/073418
Japanese Patent Application Publication No. 2007-314883
Japanese Patent No. 3086447
Japanese Patent Application Publication No. H7-76771
Japanese Translation of PCT International Application Publication No. 2008-533299

### SUMMARY OF THE INVENTION

### Problems to be Solved by the Invention

In light of the foregoing points, an object of the present invention is to provide a tungsten sintered compact target capable of stably reducing the electrical resistivity in a tungsten film deposited using a tungsten sintered compact target.

### Means for Solving the Problems

In order to achieve the foregoing object, the present inventors provide the following invention.

1) A tungsten sintered compact sputtering target, wherein a molybdenum strength detected with a secondary ion mass spectrometer (D-SIMS) is equal to or less than 1/10000 of the tungsten strength.

2) A tungsten sintered compact sputtering target, wherein a molybdenum strength detected with a secondary ion mass spectrometer (D-SIMS) is equal to or less than 1/100000 of the tungsten strength.

3) A tungsten sintered compact sputtering target, wherein a molybdenum strength detected with a secondary ion mass spectrometer (D-SIMS) is equal to or less than 1/1000000 of the tungsten strength.

4) The tungsten sintered compact sputtering target according to any one of 1) to 3) above, wherein a film resistance after subjecting a sputtered film to heating treatment (heat treatment) at 850° C. for 60 minutes is 95% or less in comparison to a sputtered film that was not subject to heat treatment (non-heat treated sputtered film).

The tungsten sintered compact sputtering target according to any one of claims 1 to 4, wherein a molybdenum content in the tungsten target used in sputtering is 3 ppm or less.

In the tungsten sintered compact sputtering target, the film resistance after subjecting a sputtered film to heating treatment (heat treatment) at 850° C. for 60 minutes is preferably 92% or less, and more preferably 90% or less, in comparison to a sputtered film that was not subject to heat treatment (non-heat treated sputtered film).

5) The tungsten sintered compact sputtering target according to any one of 1) to 4) above, wherein a molybdenum content in the tungsten target used in sputtering is 3 ppm or less.

The molybdenum content in the tungsten target used in the foregoing sputtering process is preferably 1 ppm or less, and more preferably 0.1 ppm or less.

6) The tungsten sintered compact sputtering target according to any one of 1) to 9) above, wherein, based on a grain size distribution measurement of a W powder used during sintering, sintering is performed using a W powder in which a grain size ratio of tungsten grains of 10 μm or less is 30% or more and less than 70%.

7) A tungsten thin film deposited using the tungsten sintered compact sputtering target according to any one of 1) to 6) above.

### Effect of the Invention

The present invention mainly provides a tungsten sintered compact sputtering target, wherein the molybdenum strength detected with a secondary ion mass spectrometer (D-SIMS) is equal to or less than 1/10000 of the tungsten strength, and yields a superior effect of being able to stably reduce the electrical resistivity in a tungsten film that is sputter-deposited using a tungsten sintered compact sputtering target.

### BRIEF DESCRIPTION OF THE DRAWINGS

FIG. 1 is a diagram showing the data (sample A) of the grain size distribution of the W raw material powder of Example 1.

FIG. 2 is a diagram showing the data (sample C) of the grain size distribution of the W raw material powder of Comparative Example 1.

### DETAILED DESCRIPTION

The tungsten sintered compact sputtering target of the present invention is characterized in that the molybdenum strength detected with a secondary ion mass spectrometer (D-SIMS) is equal to or less than 1/10000 of the tungsten strength, the molybdenum strength detected with a secondary ion mass spectrometer (D-SIMS) is preferably equal to or less than 1/100000 of the tungsten strength, and the molybdenum strength detected with a secondary ion mass spectrometer (D-SIMS) is more preferably equal to or less than 1/1000000 of the tungsten strength. This is the basic invention of the present invention. Note that the molybdenum strength and the tungsten strength in the thin film also take on the same values as those of the target.

There is a problem in that a tungsten thin film has a high specific resistance that is double that of its theoretical specific resistance, and its inherent high conductivity is not being sufficiently yielded. Thus, there are cases where a tungsten thin film is used upon reducing its resistance by eliminating the dislocation in the thin film via heat treatment.

According to Patent Document 1 (Japanese Patent Application Publication No. 2001-295036), up to roughly 100 ppm is tolerated as the molybdenum concentration in a target, but when this kind of large amount of molybdenum exists in the target, and consequently in the thin film, it has been discovered that the effect of being able to reduce the specific resistance of the film via heat treatment is impaired.

Thus, as a result of intense study, the present inventors discovered that, as a solution to the foregoing problem, the film resistance can be efficiently reduced when, in a tungsten sintered compact sputtering target, the molybdenum strength in the thin film detected with a secondary ion mass spectrometer (D-SIMS) is equal to or less than 1/10000 of the tungsten strength. The present invention discovered the requirements for realizing the above.

Moreover, the present invention additionally provides the foregoing tungsten sintered compact sputtering target, wherein the film resistance after subjecting the sputtered film to heating treatment (heat treatment) at 850° C. for 60 minutes is 95% or less, preferably 92% or less, and more preferably 90% or less, in comparison to a sputtered film that was not subject to heat treatment (non-heat treated sputtered film). This further describes the characteristics and features offered by the tungsten sintered compact sputtering target of the present invention.

Moreover, the heating treatment (heat treatment) at 850° C. for 60 minutes shows the conditions of standard heating treatment that is performed as needed in a tungsten sintered compact sputtering target, and while heating treatment may also be performed under conditions that are different from the foregoing temperature and time, the foregoing conditions represent an index capable of realizing the characteristics of the target of the present invention based on the foregoing temperature and time. Accordingly, conditions of this heating treatment (heat treatment) within the range of the film resistance are covered by the present invention.

The present invention additionally provides the foregoing tungsten sintered compact sputtering target, wherein the molybdenum content in the tungsten target used in sputtering is 3 ppm or less, preferably 1 ppm or less, and more preferably 0.1 ppm or less. This further describes the characteristics and features offered by the tungsten sintered compact sputtering target of the present invention.

As described above, reduction of the molybdenum content enables the stable reduction of the electrical resistivity of a tungsten sputtering film.

Moreover, the present invention additionally provides a sintered compact sputtering target, wherein, based on the grain size distribution measurement of a W powder used during sintering, sintering is performed using a W powder in which the grain size ratio of tungsten grains of 10 μm or less is 30% or more and less than 70%, and further based on the grain size distribution measurement, sintering is performed using a W powder in which the grain size ratio of tungsten grains of 10 μm or less is 50% or more and less than 70%.

These are the effective conditions upon realizing the foregoing tungsten sintered compact sputtering target of the present invention. This further describes the characteristics and features offered by the tungsten sintered compact sputtering target of the present invention.

When performing measurement based on the grain size distribution measurement, primary grains or secondary grains can be measured. The W powder to be used may be primary grains or secondary grains. The upper limit of 70% is set because, if the grains are too fine, the bulk density will decrease excessively when the grains are filled during hot press, and consequently deteriorate the productivity (number of targets that can be produced at once will decrease). The characteristic values in cases of changing the value of the grain size distribution of the W powder used during sintering will be in detail with reference to the Examples and Comparative Examples described later.

In addition, the present invention covers a tungsten thin film that is deposited using the foregoing tungsten sintered compact sputtering target. The tungsten sputtering film sputtered using a tungsten sintered compact sputtering target with a reduced molybdenum content reflects the foregoing reduction of molybdenum, and enables the stable reduction of electrical resistance of the tungsten film.

Note that SIMS is preferably used for viewing the Mo distribution. SIMS is a preferred measurement means since it can perform measurement even in a micro area of a thin film.

During sintering, it is effective to perform hot press (HP) at a temperature exceeding 1500° C. After the hot press, HIP treatment can be performed at a temperature exceeding 1600° C. in order to further improve the density.

Moreover, it is possible to provide a tungsten sintered compact sputtering target having a relative density of 99% or higher, and even 99.5% or higher. Improvement of density is favorable since it can increase the strength of the target.

Since the improvement in the density will reduce holes and cause the crystal grains to become refined, and cause the sputtered surface of the target to become uniform and smooth, the present invention yields the effect of being able to reduce the generation of particles and nodules during the sputtering process and additionally extend the target life, and also yields the effect of being able to reduce the variation in quality and improve mass productivity.

Thus, simultaneously with being able to reduce the specific resistance of the tungsten film that is deposited by using a tungsten target, the target structure is uniformized in the diameter direction and the thickness direction of the target, the target strength is also sufficient, and there are no problems such as the target cracking during the operation or use thereof. Accordingly, it is possible to improve the production yield of the target.

### EXAMPLES

The present invention is now explained based on the Examples and Comparative Examples. These Examples are merely illustrative, and the present invention shall in no way be limited thereby. In other words, various modifications and other embodiments based on the technical spirit claimed in the claims shall be included in the present invention as a matter of course.

### Example 1

A raw material having a Mo concentration of 1 wt % in Na₂WO₄ was subject to sulfidization treatment once, the obtained ammonium tungstate was subject to “calcination” to obtain a tungsten oxide, and the obtained tungsten oxide was subject to hydrogen reduction to cause the molybdenum concentration in the high purity tungsten powder to be 3 wtppm. The Mo amount was measured with the wet process. Hydrogen reduction was performed based on the following methods 1) and 2) to obtain a tungsten raw material powder.

1) Hydrogen reduction is performed at a hydrogen flow rate of 10 L/min to obtain a raw material in which the grain size (secondary grain size) of tungsten powder of 10 μm or less is 20%. As a specific example, when the size of the reducing furnace is 2 L, used is a raw material that is produced at a flow rate of replacing hydrogen in the reducing furnace five times in one minute.

2) Hydrogen reduction is performed at a hydrogen flow rate of 30 L/min to obtain a raw material in which the grain size (secondary grain size) of tungsten powder of 10 μm or less is 80%. As a specific example, when the size of the reducing furnace is 2 L, used is a raw material that is produced at a flow rate of replacing hydrogen in the reducing furnace fifteen times in one minute.

The foregoing sulfidization treatment is performed based on the following method.

The starting raw material is a sodium tungstate aqueous solution. Sulfidized Na and sulfuric acid were added to the aqueous solution, and the sulfide of Mo was precipitated and separated. Subsequently, sodium hydroxide and calcium salt were added to recover calcium tungstate, hydrochloric acid was further added to the obtained calcium tungstate, and decomposed to obtain tungstic acid (WO₃). Subsequently, ammonia was added thereto to obtain an ammonium tungstate aqueous solution.

The calcination may be suitably performed within the following conditions of 600 to 900° C.×30 minutes to 3 hours.

The sulfidization treatment described above is merely an example, and without limitation to such treatment, any other means may be adopted so as long an ammonium tungstate aqueous solution can be obtained.

Filled in a carbon die were a tungsten powder (48%) having a purity of 99.999% and in which a grain size (secondary grain size) of 10 μm or less is 20%, and a tungsten powder (52%) having a purity of 99.999% and in which a grain size (secondary grain size) of 10 μm or less is 80%.

Subsequently, after hermetically sealing the carbon die with an upper punch and a lower punch, a pressure of 210 kgf/cm² was applied to the die, the die was heated at 1200° C. via external heating and held for 6 hours thereafter, and then hot press was performed. The maximum temperature was 1600° C.×2 hours. The hot press shape was φ (diameter) 456 mm×10 mmt (thickness).

After the HP, HIP treatment was performed at 1750° C. for 5 hours. The relative density of the obtained tungsten sintered compact was 99.0%, the Mo/W strength ratio was 1:34,000, the Mo concentration in the target was 3 ppm, the grain size distribution (ratio of 10 μm or less) of the W powder as the sintering raw material was 51%, and the specific resistance after the heat treatment performed at 850° C. for 60 minutes was 94%. These results are shown in Table 1. All of these results satisfied the conditions of the present invention.

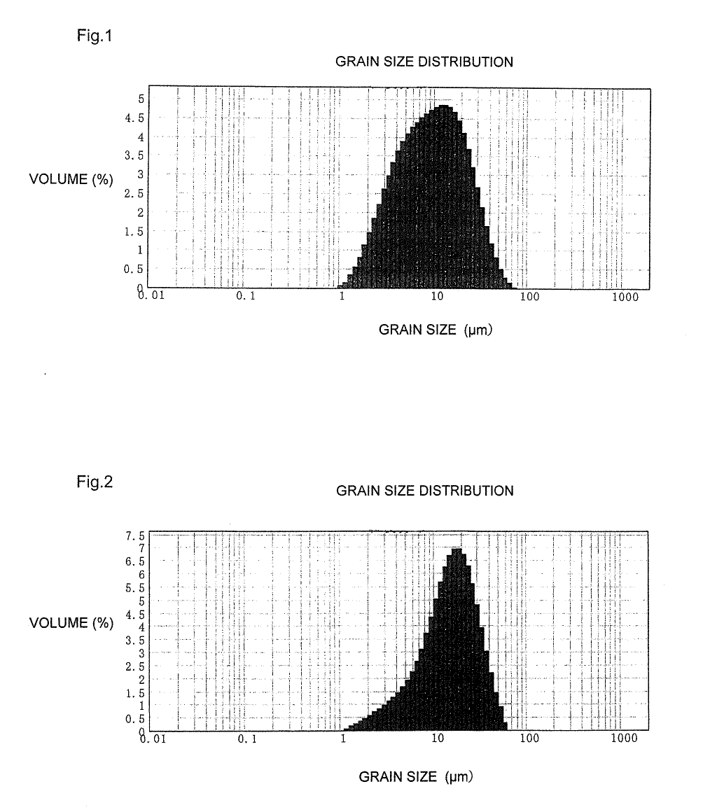

Note that the data (sample A) of the grain size distribution of the W raw material powder of Example 1 is shown in FIG. 1.

TABLE 1

| | | | Grain size distribution | Specific resistance after |
|---|---|---|---|---|
| | Mo/W strength | Mo concentration | (ratio % of 10 μm | heat treatment at |
| | ratio | in target | or less) | 850° C. for 60 minutes |
| Example 1 | 1:34,000 | 3 ppm | 51 | 94% |
| Example 2 | 1:210,000 | 0.9 ppm | 45 | 91% |
| Example 3 | 1:1,700,000 | 0.07 ppm | 38 | 89% |
| Comparative | 1:8,000 | 15 ppm | 27 | 97% |
| Example 1 | | | | |
| Comparative | 1:1,100 | 75 ppm | 22 | 97% |
| Example 2 | | | | |

### Example 2

A raw material having a Mo concentration of 1 wt % in Na₂WO₄ was subject to sulfidization treatment twice, the obtained ammonium tungstate was subject to “calcination” to obtain a tungsten oxide, and the obtained tungsten oxide was subject to hydrogen reduction to cause the molybdenum concentration in the high purity tungsten powder to be 0.9 wtppm. The Mo amount was measured with the wet process. Hydrogen reduction was performed based on the following methods 1) and 2) to obtain a tungsten raw material powder.

1) Hydrogen reduction is performed at a hydrogen flow rate of 10 L/min to obtain a raw material in which the grain size (secondary grain size) of tungsten powder of 10 μm or less is 20%. As a specific example, when the size of the reducing furnace is 2 L, used is a raw material that is produced at a flow rate of replacing hydrogen in the reducing furnace five times in one minute.

2) Hydrogen reduction is performed at a hydrogen flow rate of 30 L/min to obtain a raw material in which the grain size (secondary grain size) of tungsten powder of 10 μm or less is 80%. As a specific example, when the size of the reducing furnace is 2 L, used is a raw material that is produced at a flow rate of replacing hydrogen in the reducing furnace fifteen times in one minute.

Filled in a carbon die were a tungsten powder (58%) having a purity of 99.999% and in which a grain size (secondary grain size) of 10 μm or less is 20%, and a tungsten powder (42%) having a purity of 99.999% and in which a grain size (secondary grain size) of 10 μm or less is 80%.

Subsequently, after hermetically sealing the carbon die with an upper punch and a lower punch, a pressure of 210 kgf/cm² was applied to the die, the die was heated at 1200° C. via external heating and held for 4 hours thereafter, and then hot press was performed. The maximum temperature was 1570° C.×2 hours. The hot press shape was φ (diameter) 456 mm×10 mmt (thickness).

After the HP, HIP treatment was performed at 1850° C. for 5 hours. The relative density of the obtained tungsten sintered compact was 99.0%, the average grain size was 32.1 μm, the Mo/W strength ratio was 1:210,000, the Mo concentration in the target was 0.9 ppm, the grain size distribution (ratio of 10 μm or less) of the W powder as the sintering raw material was 45%, and the specific resistance after the heat treatment performed at 850° C. for 60 minutes was 91%. These results are shown in Table 1. All of these results satisfied the conditions of the present invention.

### Example 3

A raw material having a Mo concentration of 0.1 wt % in Na₂WO₄ was subject to sulfidization treatment twice, the obtained ammonium tungstate was subject to “calcination” to obtain a tungsten oxide, and the obtained tungsten oxide was subject to hydrogen reduction to cause the molybdenum concentration in the high purity tungsten powder to be 0.07 wtppm. The Mo amount was measured with the wet process. Hydrogen reduction was performed based on the following methods 1) and 2) to obtain a tungsten raw material powder.

1) Hydrogen reduction is performed at a hydrogen flow rate of 10 L/min to obtain a raw material in which the grain size (secondary grain size) of tungsten powder of 10 μm or less is 20%. As a specific example, when the size of the reducing furnace is 2 L, used is a raw material that is produced at a flow rate of replacing hydrogen in the reducing furnace five times in one minute.

2) Hydrogen reduction is performed at a hydrogen flow rate of 30 L/min to obtain a raw material in which the grain size (secondary grain size) of tungsten powder of 10 μm or less is 80%. As a specific example, when the size of the reducing furnace is 2 L, used is a raw material that is produced at a flow rate of replacing hydrogen in the reducing furnace fifteen times in one minute.

Filled in a carbon die were a tungsten powder (70%) having a purity of 99.999% and in which a grain size (secondary grain size) of 10 μm or less is 20%, and a tungsten powder (30%) having a purity of 99.999% and in which a grain size (secondary grain size) of 10 μm or less is 80%.

Subsequently, after hermetically sealing the carbon die with an upper punch and a lower punch, a pressure of 210 kgf/cm² was applied to the die, the die was heated at 1200° C. via external heating and held for 4 hours thereafter, and then hot press was performed. The maximum temperature was 1570° C.×2 hours. The hot press shape was φ (diameter) 456 mm×10 mmt (thickness).

After the HP, HIP treatment was performed at 1570° C. for 5 hours. The relative density of the obtained tungsten sintered compact was 99.0%, the average grain size was 39.7 μm, the Mo/W strength ratio was 1:1,700,000, the Mo concentration in the target was 0.07 ppm, the grain size distribution (ratio of 10 μm or less) of the W powder as the sintering raw material was 38%, and the specific resistance after the heat treatment performed at 850° C. for 60 minutes was 89%. These results are shown in Table 1. All of these results satisfied the conditions of the present invention.

### Comparative Example 1

A raw material having a Mo concentration of 10 wt % in Na₂WO₄ was subject to sulfidization treatment once, the obtained ammonium tungstate was subject to “calcination” to obtain a tungsten oxide, and the obtained tungsten oxide was subject to hydrogen reduction to cause the molybdenum concentration in the high purity tungsten powder to be 15 wtppm.

The Mo amount was measured with the wet process. Hydrogen reduction was performed based on the following methods 1) and 2) to obtain a tungsten raw material powder.

1) Hydrogen reduction is performed at a hydrogen flow rate of 10 L/min to obtain a raw material in which the grain size (secondary grain size) of tungsten powder of 10 μm or less is 20%. As a specific example, when the size of the reducing furnace is 2 L, used is a raw material that is produced at a flow rate of replacing hydrogen in the reducing furnace five times in one minute.

2) Hydrogen reduction is performed at a hydrogen flow rate of 30 L/min to obtain a raw material in which the grain size (secondary grain size) of tungsten powder of 10 μm or less is 80%. As a specific example, when the size of the reducing furnace is 2 L, used is a raw material that is produced at a flow rate of replacing hydrogen in the reducing furnace fifteen times in one minute.

Filled in a carbon die were a tungsten powder (88%) having a purity of 99.999% and in which a grain size (secondary grain size) of 10 μm or less is 20%, and a tungsten powder (12%) having a purity of 99.999% and in which a grain size (secondary grain size) of 10 μm or less is 80%, and this was wrapped with a carbon sheet.

Subsequently, after hermetically sealing the carbon die with an upper punch and a lower punch, a pressure of 210 kgf/cm² was applied to the die, the die was heated at 1200° C. via external heating and held for 2 hours thereafter, and then hot press was performed. The maximum temperature was 1800° C.×2 hours. The hot press shape was φ (diameter) 456 mm×10 mmt (thickness).

After the HP, HIP treatment was performed at 1850° C. for 5 hours. The relative density of the obtained tungsten sintered compact was 99.2%, the average grain size was 22.5 μm, the Mo/W strength ratio was 1:8,000, the Mo concentration in the target was 15 ppm, the grain size distribution (ratio of 10 μm or less) of the W powder as the sintering raw material was 27%, and the specific resistance after the heat treatment performed at 850° C. for 60 minutes was 97%. These results are shown in Table 1. The data (sample C) of the grain size distribution of the W raw material powder of Comparative Example 1 is shown in FIG. 1.

Consequently, the Mo/W strength ratio, the Mo concentration in the target, the grain size distribution (ratio of 10 μm or less) of the W powder, and the specific resistance after the heat treatment performed at 850° C. for 60 minutes all failed to satisfy the conditions of the present invention.

### Comparative Example 2

A raw material having a Mo concentration of 1 wt % in Na₂WO₄ was subject to sulfidization treatment once, the obtained ammonium tungstate was subject to “calcination” to obtain a tungsten oxide, and the obtained tungsten oxide was subject to hydrogen reduction to cause the molybdenum concentration in the high purity tungsten powder to be 3 wtppm.

The Mo amount was measured with the wet process. Hydrogen reduction was performed based on the following method 1) to obtain a tungsten powder, and Mo was further added to obtain a tungsten raw material powder having a predetermined Mo concentration (75 wtppm).

1) Hydrogen reduction is performed at a hydrogen flow rate of 10 L/min to obtain a raw material in which the grain size (secondary grain size) of tungsten powder of 10 μm or less is 20%. As a specific example, when the size of the reducing furnace is 2 L, used is a raw material that is produced at a flow rate of replacing hydrogen in the reducing furnace five times in one minute.

Filled in a carbon die was a tungsten powder (100%) having a purity of 99.999% and in which a grain size (secondary grain size) of 10 μm or less is 20%.

Subsequently, after hermetically sealing the carbon die with an upper punch and a lower punch, a pressure of 210 kgf/cm² was applied to the die, the die was heated at 1200° C. via external heating and held for 2 hours thereafter, and then hot press was performed. The maximum temperature was 1400° C.×2 hours. The hot press shape was φ (diameter) 456 mm×10 mmt (thickness).

After the HP, HIP treatment was performed at 1570° C. for 5 hours. The relative density of the obtained tungsten sintered compact was 99.0%, the average grain size was 69.7 μm, the Mo/W strength ratio was 1:1,100, the Mo concentration in the target was 75 ppm, the grain size distribution (ratio of 10 μm or less) of the W powder as the sintering raw material was 22%, and the specific resistance after the heat treatment performed at 850° C. for 60 minutes was 97%. These results are shown in Table 1. Consequently, the Mo/W strength ratio, the Mo concentration in the target, the grain size distribution (ratio of 10 μm or less) of the W powder, and the specific resistance after the heat treatment performed at 850° C. for 60 minutes all failed to satisfy the conditions of the present invention.

The tungsten sintered compact targets prepared with Example 1 and Comparative Example 1 were used to form a tungsten film on a silicon substrate via sputtering, and the specific resistance of the film was measured. An FIB device was used to measure the film thickness and calculate the deposition rate of the film that was deposited so that the film thickness would be approximately 1000 Å. The sheet resistance was separately measured.

The specific resistance of the film was obtained from the foregoing values. Consequently, the specific resistance of Example 1 was 11.47 μΩ·cm, and it was confirmed that the specific resistance decreased by 3% in comparison to the specific resistance of 11.83 μΩ·cm of Comparative Example 1. Note that it is extremely difficult to reduce the specific resistance of a tungsten film, and in this respect it could be said that the reduction of 3% is a significant effect.

The present invention mainly provides a tungsten sintered compact sputtering target, wherein the molybdenum strength detected with a secondary ion mass spectrometer (D-SIMS) is equal to or less than 1/10000 of the tungsten strength, and yields a superior effect of being able to stably reduce the electrical resistivity in a tungsten film that is sputter-deposited using a tungsten sintered compact sputtering target. Accordingly, the tungsten sintered compact sputtering target of the present invention is effective for the usage in forming an electrode material or a wiring material for VLSI.

1. A tungsten sintered compact sputtering target, wherein, based on a grain size distribution measurement of a W powder used during sintering, sintering is performed using a W powder in which a grain size ratio of tungsten grains of 10 μm or less is 30% or more and less than 70%.

2. The tungsten sintered compact sputtering target according to claim 1, wherein a molybdenum strength detected with a secondary ion mass spectrometer (D-SIMS) is equal to or less than 1/100000 of the tungsten strength.

3. The tungsten sintered compact sputtering target according to claim 1, wherein a molybdenum strength detected with a secondary ion mass spectrometer (D-SIMS) is equal to or less than 1/1000000 of the tungsten strength.

4. The tungsten sintered compact sputtering target according to claim 3, wherein a film resistance after subjecting a sputtered film to heating treatment (heat treatment) at 850° C. for 60 minutes is 95% or less in comparison to a sputtered film that was not subject to heat treatment (non-heat treated sputtered film).

5. The tungsten sintered compact sputtering target according to claim 4, wherein a molybdenum content in the tungsten sintered compact sputtering target is 3 ppm or less.

6. (canceled)

7. A tungsten thin film deposited using the tungsten sintered compact sputtering target according to claim 6.

8. The tungsten sintered compact sputtering target according to claim 1, wherein a molybdenum strength of the sputtering target detected with a secondary ion mass spectrometer (D-SIMS) is equal to or less than 1/10000 of a tungsten strength of the sputtering target.

9. The tungsten sintered compact sputtering target according to claim 1, wherein a molybdenum content in the tungsten sintered compact sputtering target is 3 ppm or less.

10. A tungsten thin film deposited using the tungsten sintered compact sputtering target according to claim 1.

11. The tungsten thin film according to claim 10, wherein a film resistance after subjecting the tungsten thin film to heat treatment of 850° C. for 60 minutes is 95% or less in comparison to a tungsten thin film not subject to said heat treatment.
